(19) United States
(12) Patent Application Publication
(10) Pub. No.: US 2023/0268842 A1
(43) Pub. Date: Aug. 24, 2023

(54) INVERTER

(71) Applicant: Sungrow Power Supply Co., Ltd, Hefei (CN)

(72) Inventors: Hao Zheng, Hefei (CN); Xiaohu Wang, Hefei (CN); Qiyao Zhu, Hefei (CN); Wentao Shu, Hefei (CN); Ye Yang, Hefei (CN); Guoqi Zhang, Hefei (CN)

(73) Assignee: Sungrow Power Supply Co., Ltd, Hefei (CN)

(21) Appl. No.: 18/170,721

(22) Filed: Feb. 17, 2023

(30) Foreign Application Priority Data
Feb. 22, 2022 (CN) 202220365285.9

(51) Int. Cl. H02M 7/00; H05K 7/20; H05K 7/14

(52) U.S. Cl. CPC H02M 7/003; H05K 7/20909; H05K 7/1432

(57) ABSTRACT

An inverter is provided according to the present disclosure. The inverter is configured with a first direction and a second direction, the first direction and the second direction are vertical to each other, and a length of the inverter in the first direction is greater than a length of the inverter in the second direction; the inverter comprises a direct current device and an inversion alternating current device, and the direct current device and the inversion alternating current device are arranged along the first direction and electrically connected; wherein the direct current device and the inversion alternating current device are arranged alternately; or the inversion alternating current device is arranged collectively and the direct current device is arranged on an outside of the alternating current device.

The application claims priority to Chinese Patent Application No. 202220365285.9, titled “INVERTER”, filed on Feb. 22, 2022, with the China National Intellectual Property Administration, which is incorporated herein by reference in its entirety.

### FIELD

The present disclosure relates to the field of inverter technology, and in particular, to an inverter.

### BACKGROUND

An inverter is a converter that converts direct current power into alternating current power in constant frequency and constant voltage or frequency modulation and voltage modulation. A photovoltaic grid-connected inverter, as an interface device between the solar power generation system and power grid, is widely used in production operations.

With the increasing demand of users for higher power of the photovoltaic grid-connected inverter, the size of inverter is also becoming larger and larger. Therefore, the internal modules of the inverter are generally designed compactly. However, due to the compact structure of the inverter, it is sacrificed the assembly and maintenance side, resulting in poor maintenance experience.

### SUMMARY

A purpose of the present disclosure is to provide an inverter to improve the assembly and maintenance experience.

In order to achieve the above object, an inverter is provided according to the present disclosure. The inverter is configured with a first direction and a second direction, wherein the first direction and the second direction are vertical to each other, and a length of the inverter in the first direction is greater than a length of the inverter in the second direction; the inverter comprises a direct current device and an inversion alternating current device, and the direct current device and the inversion alternating current device are arranged along the first direction and electrically connected;

wherein the direct current device and the inversion alternating current device are arranged alternately; or the inversion alternating current device is arranged collectively and the direct current device is arranged on an outside of the alternating current device.

In an embodiment, the direct current device comprises a direct current power distribution part and a control unit, and the direct current power distribution part and the control unit are arranged along the second direction and electrically connected;

the inversion alternating current device includes a power unit, an alternating current power distribution part and a reactor, the alternating current power distribution part and the reactor are arranged along the second direction, the power unit, the alternating current power distribution part and the reactor are arranged along a third direction, and the third direction is vertical to the first direction and the second direction; and

wherein the direct current power distribution part, the power unit, the reactor and the alternating current power distribution part are electrically connected in sequence.

In an embodiment, the power unit comprises a direct current capacitor pool assembly and an inverter module, and the direct current capacitor pool assembly and the inverter module are arranged along the second direction;

the direct current capacitor pool assembly and the alternating current power distribution part are arranged along the third direction, and the inverter module and the reactor are arranged along the third direction;

wherein the direct current power distribution part, the direct current capacitor pool assembly, the inverter module, the reactor and the alternating current power distribution part are electrically connected in sequence.

In an embodiment, the inverter further comprises a housing, and the direct current device and the alternating current inverter device are both arranged in the housing.

In an embodiment, the housing is configured with a first air inlet and a first air outlet, a first heat-dissipation air channel is formed between the first air inlet and the first air outlet, and the first heat-dissipation air channel is configured to pass through the inverter module and the reactor;

the first heat-dissipation air channel is configured with a first heat-dissipation fan, and the first heat-dissipation fan is used to drive air to flow from the first air inlet into the first heat-dissipation air channel and out from the first air outlet.

In an embodiment, the housing is further configured with a third air inlet and a third air outlet, and a third heat-dissipation air channel is formed between the third air inlet and the third air outlet, and the third heat-dissipation air channel is configured to pass through the direct current capacitor pool assembly;

wherein the third heat-dissipation air channel is configured with a third heat-dissipation fan, and the third heat-dissipation fan is used to drive air to flow from the third air inlet into the third heat-dissipation air channel and out from the third air outlet.

In an embodiment, the housing is further configured with a second heat-dissipation air channel, and the second heat-dissipation air channel is configured to pass through the alternating current power distribution part and the direct current power distribution part and is configured in a closed loop; wherein the second heat-dissipation air channel is configured with a second heat-dissipation fan, and the second heat dissipation fan is used to drive air to circulate between the alternating current power distribution part and the direct current power distribution part; and

the housing is further configured with a heat exchanger, a heating terminal of the heat exchanger is located in the third heat-dissipation air channel, and a cooling terminal of the heat exchanger is located in the second heat-dissipation air channel.

In an embodiment, the housing is further configured with a fourth fan, the fourth fan is used to drive air to flow from the direct current power distribution part to the alternating current power distribution part, and/or, the fourth fan is used to drive air to flow from the alternating current power distribution part to the direct current power distribution part.

In an embodiment, at least two direct current devices and at least two inversion alternating current devices are arranged alternately along the first direction; or at least two inversion alternating current devices are arranged in sequence along the first direction, and at least two direct current devices are arranged on two sides of the at least two inversion alternating current devices along the first direction.

In an embodiment, at least two inverters are arranged in sequence along the first direction.

According to the technical solution of the present disclosure, an inverter is configured with a first direction and a second direction, wherein the first direction and the second direction are vertical to each other, and a length of the inverter in the first direction is greater than a length of the inverter in the second direction; the inverter comprises a direct current device and an inversion alternating current device, and the direct current device and the inversion alternating current device are arranged along the first direction and electrically connected. In this way, the staff can perform assembly and maintenance operations on two sides (the front and back sides) of the inverter along the first direction. Since the assembly and maintenance side is wide, the assembly and maintenance operations are convenient, which can effectively improve the assembly and maintenance experience of the staff. In addition, the direct current device and the inversion alternating current device are arranged alternately; or the inversion alternating current device is arranged collectively and the direct current device is arranged on an outside of the inversion alternating current device. The above two arrangements are beneficial to heat dissipation of the inverter.

### BRIEF DESCRIPTION OF THE DRAWINGS

In order to more clearly illustrate the technical solutions in the embodiments of the present disclosure or in the conventional technology, the accompanying drawings used in the description of the embodiments or the conventional technology are briefly introduced hereinafter. It is apparent that the drawings in the following description illustrate merely embodiments of the present disclosure. Other drawings may be obtained by those skilled in the art without creative efforts based on the provided drawings.

FIG. 1 is a schematic diagram of a front structure of an inverter according to an embodiment of the present disclosure;

FIG. 2 is a schematic diagram of a back structure of the inverter in FIG. 1;

FIG. 3 is a schematic diagram of air flow direction of a first heat-dissipation air channel of the inverter in FIG. 1;

FIG. 4 is a schematic diagram of air flow direction of a second heat-dissipation air channel of the inverter in FIG. 1;

FIG. 5 is a schematic diagram of air flow direction of the second heat-dissipation air channel of the inverter in FIG. 1;

FIG. 6 is a schematic diagram of air flow directions of the second heat-dissipation air channel and the third heat-dissipation air channel of the inverter in FIG. 1;

FIG. 7 is a schematic structural diagram of a fourth fan of the inverter in FIG. 1;

FIG. 8 is a schematic structural diagram of a layout of the direct current device and the inversion alternating current device of the inverter in FIG. 1; and

FIG. 9 is a schematic structural diagram of another layout of the direct current device and the inversion alternating current device of the inverter in FIG. 1.

### EXPLANATION OF REFERENCE NUMBERS

| Reference | | Reference | |
|---|---|---|---|
| number | Item | number | Item |
| 100 | Inverter | 30 | Housing |
| 10 | Direct current device | 41 | First air inlet |
| 11 | Direct current power | 42 | First air outlet |
| | distribution part | | |
| 111 | Direct current switch | 43 | First heat-dissipation air |
| | | | channel |
| 112 | Direct current branch fuse | 44 | First fan |
| 113 | Direct current input terminal | 51 | Third air inlet |
| 12 | Control unit | 52 | Third air outlet |
| 20 | Inversion alternating current | 53 | Third heat-dissipation air |
| | device | | channel |
| 21 | Direct current capacitor pool | 54 | Third fan |
| | assembly | | |
| 22 | Inverter module | 61 | Second heat-dissipation air |
| | | | channel |
| 23 | Alternating current power | 62 | Second fan |
| | distribution part | | |
| 231 | Alternating current | 63 | Fourth fan |
| | component | | |
| 232 | Alternating current switch | 70 | Heat exchanger |
| 233 | Alternating current output | 71 | Heating terminal |
| | terminal | | |
| 24 | Reactor | 72 | Cooling terminal |

The implementation of the object, functional characteristics and advantages of the present disclosure will be further described in conjunction with the embodiments and with reference to the accompanying drawings.

### DETAILED DESCRIPTION OF EMBODIMENTS

The technical solutions in the embodiments of the present disclosure will be described clearly and completely hereinafter in combination with the drawings in the embodiments of the present disclosure. It is apparent that the described embodiments are merely a part of the embodiments of the present disclosure, rather than all the embodiments. Based on the embodiments of the present disclosure, all other embodiments obtained by those skilled in the art without creative efforts pertain to the protection scope of the present disclosure.

It should be noted that if there is a directional indication (such as up, down, left, right, front, back, etc.) in the embodiments of the present disclosure, the directional indication is only used to explain the relative positional relationship, movement conditions and the like between the components (as shown in the figure) in a specific posture. If the specific posture changes, the directional indication will also change accordingly.

In addition, if there are descriptions involving “first”, “second”, and the like in the embodiments of the present disclosure, such descriptions of “first”, “second”, and the like are only used to describe the purpose, rather than indicating or implying their relative importance or implying the number of technical features indicated. Thus, the features defined as “first” and “second” may explicitly or implicitly include at least one feature. In addition, the technical solutions of the various embodiments may be combined with each other, but it must be based on those skilled in the art can implement. When the combination of technical solutions is contradictory or cannot be implemented, it should be understood that the combination of technical solutions does not exist, which is also not within the protection scope required by the present disclosure.

An inverter 100 is provided according to the present disclosure.

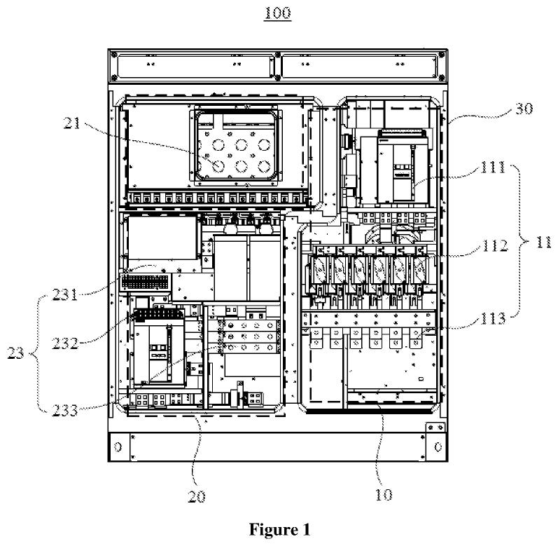

In an embodiment of the present disclosure, as shown in FIGS. 1, 2 and 5, the inverter 100 is configured with a first direction and a second direction, wherein the first direction and the second direction are vertical to each other, and a length of the inverter 100 in the first direction is greater than a length of the inverter in the second direction. The inverter 100 may include a direct current device 10 and an inversion alternating current device 20. The direct current device 10 and the inversion alternating current device 20 are arranged along the first direction and electrically connected. The direct current device and the inversion alternating current device are arranged alternately; or the inversion alternating current device is arranged collectively and the direct current device is arranged on the outside of the inversion alternating current device. In a case that there is only one direct current device and one inversion alternating current device, the direct current device and the inversion alternating current device are arranged side by side.

The inverter 100 may be applied in the field of photovoltaics and used as an interface device between the solar power generation system and the power grid, to convert the direct current converted by the solar power generation system from solar energy into alternating current through rectification, boosting and inversion to output to the power grid, thereby achieving grid-connected power supply.

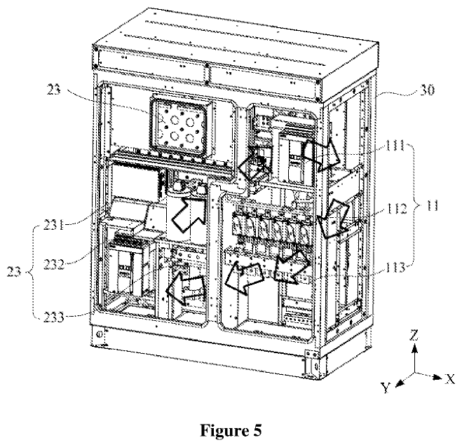

It should be noted that the X direction is the left-right direction, the Y direction is the front-rear direction, and the Z direction is the up-down direction in FIG. 5. The following descriptions about directions and coordinates may refer to FIG. 5. For example, the first direction and the second direction are both horizontal directions, and the third direction is a vertical direction, that is, the first direction is an X direction, the second direction is a Y direction, and the third direction is a Z direction.

In this embodiment, the inverter 100 including the direct current device 10 and the inversion alternating current device 20 has a cabinet structure as a whole. A direct current cabinet and an inversion alternating current cabinet are formed inside the inverter 100. The direct current cabinet is used to install direct current device 10 and the inversion alternating current cabinet is used to install the inversion alternating current device 20. The shape of the inverter 100 may be substantially rectangular, including a first side extending along the first direction and a second side extending along the second direction, and the length of the first side is greater than the length of the second side. The direct current device 10 and the inversion alternating current device 20 are arranged side by side along the long side direction of the inverter 100. In other words, the inverter 100 may select the side where the long side is located as the assembly and maintenance side and use the side where the short side is located as the cabinet connection side. In this way, staffs can perform assembly and maintenance operations on the front and back sides of the long side of the inverter 100. Since the assembly and maintenance side is wide, the assembly and maintenance operations are convenient, which can effectively improve the assembly and maintenance experience of the staffs.

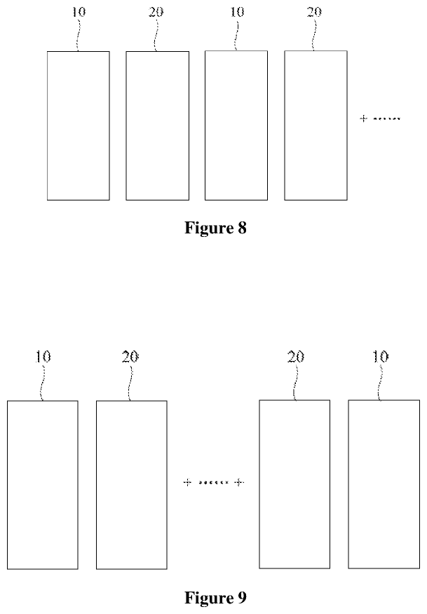

In addition, for the layout of the direct current device 10 and the inversion alternating current device 20 of the inverter 100, an uniform distribution form may be used. For example, multiple direct current devices 10 and multiple inversion alternating current devices 20 are arranged alternately along the long side of the inverter 100, which specifically may be: direct current device 10+inversion alternating current device 20+ . . . +direct current device 10+inversion alternating current device 20 (as shown in FIG. 8). Alternatively, a mirror symmetrical distribution may be used. For example, multiple inversion alternating current devices 20 are centrally arranged along the long side of the inverter 100, and the two direct current devices 10 are located on two sides of the multiple inversion alternating current devices 20, which specifically may be: direct current device 10+inversion alternating current device 20+ . . . +inversion alternating current device 20+direct current device 10 (as shown in FIG. 9). The above two arrangements are beneficial to heat dissipation of the inverter 100.

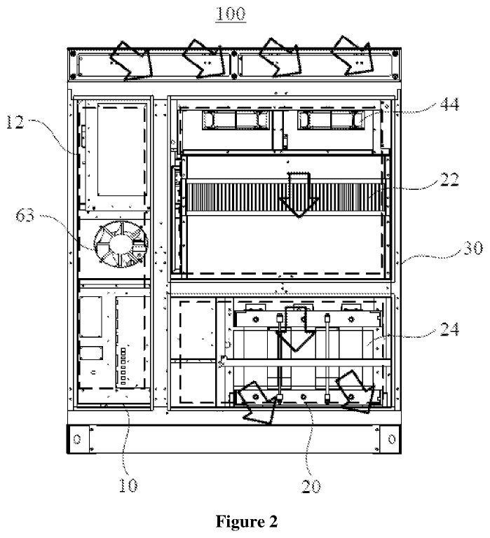

In one embodiment, referring to FIGS. 1 to 2, the direct current device 10 includes a direct current power distribution part 11 and a control unit 12, and the direct current power distribution part 11 and the control unit 12 are electrically connected and arranged along the second direction. The inversion alternating current device 20 includes a power unit, an alternating current power distribution part 23 and a reactor 24. The alternating current power distribution part 23 and the reactor 24 are arranged along the second direction. The power unit, the alternating current power distribution part 23 and the reactor 24 are arranged along the third direction, and the third direction is vertical to the first direction and the second direction. The direct current power distribution part 11, the power unit, the reactor 24 and the alternating current power distribution part 23 are electrically connected in sequence.

Specifically, the direct current power distribution part 11 may include a direct current switch 111, a direct current branch fuse 112, and a direct current input terminal 113, which are electrically connected in sequence. The alternating current power distribution part 23 may include an alternating current component 231, an alternating current switch 232 and an alternating current output terminal 233, which are electrically connected in sequence. For the layout of the direct current device 10, the direct current power distribution part 11 and the control unit 12 are arranged in front and back manner in the present embodiment, wherein the direct current power distribution part 11 is located on the front side of the long side of the inverter 100, while the control unit 12 is located on the back side of the long side of the inverter 100. Since both the front and back sides of the inverter 100 are in the wide side, the staffs may perform comprehensive maintenance on the direct current power distribution part 11 and the control unit 12. For the layout of the inversion alternating current device 20, the alternating current power distribution part 23 and the reactor 24 are arranged in front and back manner in this embodiment, the alternating current power distribution part 23 is located on the front side of the long side of the inverter 100, and the reactor 24 is located on the back side of the long side of the inverter 100. The power unit, the alternating current power distribution part 23 and the reactor 24 are arranged in up and down manner. The power unit is located above the alternating current power distribution part 23 and the reactor 24. Since both the front and back sides of the inverter 100 are in the wide side, the staffs may perform comprehensive maintenance on the alternating current power distribution part 23, the reactor 24 and the power unit. In addition, the path of the copper bars used for connecting each functional module of the main circuit is the shortest, which can save materials and costs.

In one embodiment, referring to FIGS. 1 to 2, the power unit includes a direct current capacitor pool assembly 21 and an inverter module 22, and the direct current capacitor pool assembly 21 and the inverter module 22 are arranged along the second direction; the direct current capacitor pool assembly 21 and the alternating current power distribution part 23 are arranged along the third direction, and the inverter module 22 and the reactor 24 are arranged along the third direction. The direct current power distribution part 11, the direct current capacitor pool assembly 21, the inverter module 22, the reactor 24 and the alternating current power distribution part 23 is electrically connected in sequence.

For the layout of the power unit, the direct current capacitor pool assembly 21 and the inverter module 22 are arranged in front and back manner in this embodiment, the direct current capacitor pool assembly 21 is located above the alternating current power distribution part 23, and the inverter module 22 is located above the reactor 24. The control unit 12 is used for assisting control, and the main circuit is the direct current power distribution part 11 to the direct current capacitor pool assembly 21 to the inverter module 22 to the reactor 24 and then to the alternating current power distribution part 23, so that the direct current power inputted via the inverter 100 is converted into alternating current output after being rectified, boosted, and inverted. In this embodiment, by reasonably arranging the positions of each of functional modules of the main circuit, the path of the copper bars used to connect the functional modules of the main circuit can be made the shortest, which can save materials and costs. In addition, it is beneficial to improve the regularity and order of the space of the inverter 100.

In an embodiment, referring to FIGS. 1 to 2, the inverter 100 further includes a housing 30, and the direct current device 10 and the inversion alternating current device 20 are arranged in the housing 30.

In this embodiment, the inverter 100 encloses the direct current device 10 and the inversion alternating current device 20 as a cabinet with the housing 30. The housing 30 can effectively protect the direct current device 10 and the inversion alternating current device 20 and reduce external dust and moisture from contacting the direct current device 10 and the inversion alternating current device 20, thereby reducing the possibility of the circuit damage of the direct current device 10 and the inversion alternating current device 20, and improving the working performance of the inverter 100.

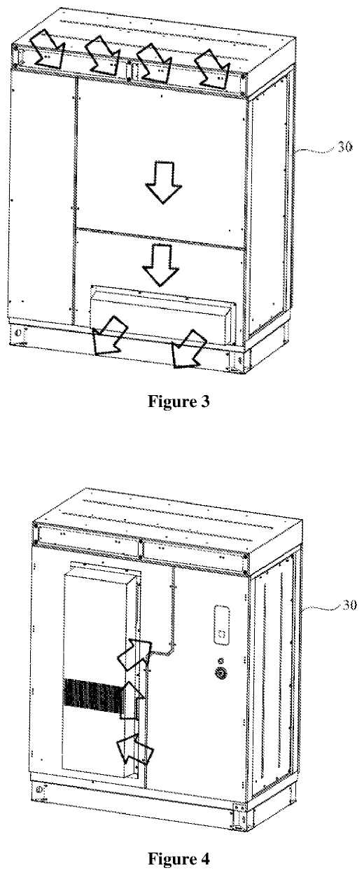

In one embodiment, referring to FIGS. 2, 3 and 6, the housing 30 may be configured with a first air inlet 41 and a first air outlet 42, and the housing 30 may form a first heat-dissipation air channel 43 between the first air inlet 41 and the first air outlet 42. The first heat-dissipation air channel 43 passes through the inverter module 22 and the reactor 24. The first heat-dissipation air channel 43 may be configured with a first heat-dissipation fan, and the first heat-dissipation fan is used to drive air to flow from the first air inlet 41 into the first heat-dissipation air channel 43 and out from the first air outlet 42.

In this embodiment, the cavity where the inverter module 22 and the reactor 24 are located on the back side of the inverter 100 forms the first heat-dissipation air channel 43. Correspondingly, the first air inlet 41 is located at the top of the back side of the inverter 100, such as the top side surface of the housing 30 or the side near the top. The first air outlet 42 is located at the bottom of the back side of the inverter 100, such as the bottom of the housing 30 or the side near the bottom. The first heat-dissipation fan may be installed between the first air inlet 41 and the inverter module 22, or between the inverter module 22 and the reactor 24, or between the reactor 24 and the first air outlet 42 and the like, the position of the first heat-dissipation fan is not limited here. In this case, the airflow direction of the first heat-dissipation air channel 43 is from top to bottom, passing through the first air inlet 41, the first fan 44, the inverter module 22, the reactor 24, and the first air outlet 42 in sequence, thereby forming a complete airflow heat-dissipation path (as shown by arrows in FIGS. 2, 3, and 6). In this embodiment, an independent air channel structure is configured for the inverter module 22 and the reactor 24 with relatively concentrated heat generation, so as to quickly dissipate heat from the inverter module 22 and the reactor 24 and improve the effect of heat dissipation. It should be noted that a bottom to up direction of heat dissipation may also be used in other embodiments, that is, the positions of the first air inlet 41 and the first air outlet 42 are exchanged, which will not be repeated here.

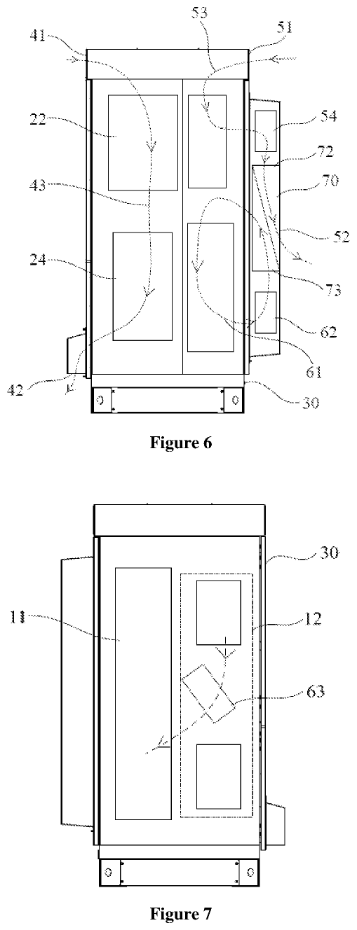

In one embodiment, referring to FIG. 6, the housing 30 may further be configured with a third air inlet 51 and a third air outlet 52, and the housing 30 may form a third heat-dissipation air channel 53 between the third air inlet 51 and the third air outlet 52. The third heat-dissipation air channel 53 passes through the direct current capacitor pool assembly 21. The third heat-dissipation air channel 53 may be configured with a third heat-dissipation fan, and the third heat-dissipation fan is used to drive air to flow from the third air inlet 51 into the third heat-dissipation air channel 53 and out from the third air outlet 52.

In this embodiment, the cavity where the direct current capacitor pool assembly 21 is located on the front side of the inverter 100 forms the third heat-dissipation air channel 53. Correspondingly, the third air inlet 51 is located at the top of the front side of the inverter 100, such as the top end surface of the housing 30 or the side near the top; the third air outlet 52 is located at the front side of the inverter 100. In this case, the heat dissipation path of the third heat-dissipation air channel 53 may be as follows: the external cold air at the top of the inverter 100, driven by the third fan 54, enters the third heat-dissipation air channel 53 from the third air inlet 51, passes through the direct current capacitor pool assembly 21, and then is discharged into the external environment from the third air outlet 52 (as shown by the arrows in FIG. 6), thereby taking away the heat generated by the direct current capacitor pool assembly 21 and implementing the heat dissipation of the direct current capacitor pool assembly 21.

In one embodiment, referring to FIGS. 4 to 6, the housing 30 is further configured with a second heat-dissipation air channel 61, and the second heat-dissipation air channel 61 passes through the alternating current power distribution part 23 and the direct current power distribution part 11 and is arranged in a closed loop. The heat dissipation air channel 61 is configured with a second heat-dissipation fan, and the second heat-dissipation fan is used to drive air to circulate between the alternating current power distribution part 23 and the direct current power distribution part 11. The housing 30 may further be configured with a heat exchanger 70, the heating terminal 71 of the heat exchanger 70 is located in the third heat-dissipation air channel 53, and the cooling terminal 72 of the heat exchanger 70 is located in the second heat-dissipation air channel 61.

In this embodiment, the second heat-dissipation air channel 61 and the third heat-dissipation air channel 53 may conjointly form an air-to-air heat exchange space, and the air-to-air heat exchanger 70 is used for heat dissipation. The heat exchanger 70 is installed on the front side of the inverter 100. The second heat-dissipation air channel 61 may constitute the inner circulation air channel of the heat exchanger 70, the third heat-dissipation air channel 53 may constitute the outer circulation air channel of the heat exchanger 70, that is, the second heat-dissipation air channel 61 is isolated from the outside environment, and the third heat-dissipation air channel 53 is communicated with the outside environment. The third heat-dissipation air channel 53 is located above the second heat-dissipation air channel 61, correspondingly, the third fan 54 is located above the heat exchanger 70, and the second heat-dissipation fan is located below the heat exchanger 70.

The heat dissipation path of the second heat dissipation air channel 61 may be as follows: the second fan 62 pushes the air upward to the cooling terminal 72 of the heat exchanger 70, and the heat exchanger 70 operates to convert the air into cold air. And then the cold air enters the cavity where the alternating current power distribution part 23 is located (as shown by the arrows in FIG. 4) to dissipate heat for the alternating current component 231, the alternating current switch 232 and the alternating current output terminal 233 of the alternating current power distribution part 23, and continues to flow to the top of the direct current device 10 to dissipate heat for the direct current switch 111, the direct current branch fuse 112, and the direct current input terminal 113 of the direct current power distribution part 11. The hot air formed by absorbing heat finally flows from the direct current device 10 back to the bottom of the inversion alternating current device 20, and enters the cooling terminal 72 of the heat exchanger 70 (as shown by the arrows in FIG. 5). Such circulation implements heat dissipation for the alternating current power distribution part 23 and the direct current power distribution part 11. At the same time, the cold air entering the third heat-dissipation air channel 53 passes through the direct current capacitor pool assembly 21, then passes through the heating terminal 71 of the heat exchanger 70, absorbs the heat released by the heat exchanger 70, becomes hot air and is discharged into the external environment, so as to satisfy the heat exchange with the second heat-dissipation air channel 61 inside the inverter 100 (as shown in FIG. 6). The airtight second heat-dissipation air channel 61 is beneficial to protect the alternating current power distribution part 23 and the direct current power distribution part 11 from the effects such as external dust and moisture.

In one embodiment, referring to FIG. 7, the housing 30 may be further configured with a fourth fan 63, the fourth fan 63 is used to drive air to flow from the direct current power distribution part 11 to the alternating current power distribution part 23, and/or the fourth fan 63 is used to drive air to flow from the alternating current power distribution part 23 to the direct current power distribution part 11.

In this embodiment, the fourth fan 63 may be installed in the middle of the control unit 12, and the fourth fan 63 may be toward the direct current power distribution part 11 and inclined downward. The fourth fan 63 may be a turbulence fan, which may disturb the air in the second heat-dissipation air channel 61 and strengthen the circulation of the air in the second heat-dissipation air channel 61 between the direct current power distribution part 11 and the alternating current power distribution part 23, so as to accelerate heat dissipation rate and improve the effect of heat dissipation.

In one embodiment, referring to FIGS. 8 to 9, at least two direct current devices 10 and at least two inversion alternating current devices 20 are arranged alternately along the first direction; and/or at least two alternating current inverter devices 20 are arranged in sequence along the first direction, and at least two direct current devices 10 are arranged on both sides of the at least two alternating current inverter devices 20 along the first direction.

In this embodiment, in addition to including one direct current device 10 and one inversion alternating current device 20, the housing 30 of the inverter 100 may also include two or more direct current devices 10 and two or more inversion alternating current devices 20, so as to increase the power level of the inverter 100 to meet the higher power requirements of the user. For the layout of the direct current device 10 and the inversion alternating current device 20 in the housing 30, an uniform distribution may be used, for example, multiple direct current devices 10 and multiple inversion alternating current devices 20 are arranged alternately along the long side of the inverter 100, which may specifically be: direct current device 10+inverting alternating current device 20+ . . . +direct current device 10+inverting alternating current device 20 (as shown in FIG. 8). Also, a mirror symmetrical distribution may be used, such as multiple inversion alternating current devices 20 are arranged in sequence along the long side of the inverter 100, and two direct current devices 10 are respectively located on two sides of multiple inversion alternating current devices 20, which may specifically be: direct current device 10+inversion alternating current device 20+ . . . +inversion alternating current device 20+direct current device 10 (as shown in FIG. 9).

In an embodiment, at least two inverters 100 are arranged in sequence along the first direction.

In this embodiment, a whole inverter 100 is used as a subset, and a “1+X” combination of inverters 100 is formed by combining multiple subsets. In a case that multiple inverters 100 are combined, the inverters 100 are combined through short sides of the inverters so that maintenance can be performed on the long sides of the inverters 100. From a single inverter 100 to a combination of multiple inverters 100, it can improve power density while increasing the power level and be more convenient for maintenance, which can reduce maintenance time.

The above are only preferred embodiments of the present disclosure and are not intended to limit the patent scope of the present disclosure. Under the inventive concept of the present disclosure, any equivalent structures variations made by using the description of the present disclosure and the contents of the accompanying drawings, or directly or indirectly used in other related technical fields, are all included in the patent protection scope of the present disclosure.

1. An inverter, wherein the inverter is configured with a first direction and a second direction, wherein the first direction and the second direction are vertical to each other, and a length of the inverter in the first direction is greater than a length of the inverter in the second direction; the inverter comprises a direct current device and an inversion alternating current device, and the direct current device and the inversion alternating current device are arranged along the first direction and electrically connected;
wherein the direct current device and the inversion alternating current device are arranged alternately; or the inversion alternating current device is arranged collectively and the direct current device is arranged on an outside of the alternating current device.

2. The inverter according to claim 1, wherein the direct current device comprises a direct current power distribution part and a control unit, and the direct current power distribution part and the control unit are arranged along the second direction and electrically connected;
the inversion alternating current device includes a power unit, an alternating current power distribution part and a reactor, the alternating current power distribution part and the reactor are arranged along the second direction, the power unit, the alternating current power distribution part and the reactor are arranged along a third direction, and the third direction is vertical to the first direction and the second direction; and
wherein the direct current power distribution part, the power unit, the reactor and the alternating current power distribution part are electrically connected in sequence.

3. The inverter according to claim 2, wherein the power unit comprises a direct current capacitor pool assembly and an inverter module, and the direct current capacitor pool assembly and the inverter module are arranged along the second direction;
the direct current capacitor pool assembly and the alternating current power distribution part are arranged along the third direction, and the inverter module and the reactor are arranged along the third direction;
wherein the direct current power distribution part, the direct current capacitor pool assembly, the inverter module, the reactor and the alternating current power distribution part are electrically connected in sequence.

4. The inverter according to claim 3, wherein the inverter further comprises a housing, and the direct current device and the inversion alternating current device are arranged in the housing.

5. The inverter according to claim 4, wherein the housing is configured with a first air inlet and a first air outlet, a first heat-dissipation air channel is formed between the first air inlet and the first air outlet, and the first heat-dissipation air channel is configured to pass through the inverter module and the reactor;
wherein the first heat-dissipation air channel is configured with a first heat-dissipation fan, and the first heat-dissipation fan is used to drive air to flow from the first air inlet into the first heat-dissipation air channel and out from the first air outlet.

6. The inverter according to claim 4, wherein the housing is further configured with a third air inlet and a third air outlet, and a third heat-dissipation air channel is formed between the third air inlet and the third air outlet, and the third heat-dissipation air channel is configured to pass through the direct current capacitor pool assembly;
wherein the third heat-dissipation air channel is configured with a third heat-dissipation fan, and the third heat-dissipation fan is used to drive air to flow from the third air inlet into the third heat-dissipation air channel and out from the third air outlet.

7. The inverter according to claim 6, wherein the housing is further configured with a second heat-dissipation air channel, and the second heat-dissipation air channel is configured to pass through the alternating current power distribution part and the direct current power distribution part and is configured in a closed loop; wherein the second heat-dissipation air channel is configured with a second heat-dissipation fan, and the second heat dissipation fan is used to drive air to circulate between the alternating current power distribution part and the direct current power distribution part; and
the housing is further configured with a heat exchanger, a heating terminal of the heat exchanger is located in the third heat-dissipation air channel, and a cooling terminal of the heat exchanger is located in the second heat-dissipation air channel.

8. The inverter according to claim 7, wherein the housing is further configured with a fourth fan, the fourth fan is used to drive air to flow from the direct current power distribution part to the alternating current power distribution part, and/or, the fourth fan is used to drive air to flow from the alternating current power distribution part to the direct current power distribution part.

9. The inverter according to claim 1, wherein at least two direct current devices and at least two inversion alternating current devices are arranged alternately along the first direction; or
at least two inversion alternating current devices are arranged in sequence along the first direction, and at least two direct current devices are arranged on two sides of the at least two inversion alternating current devices along the first direction.

10. The inverter according to claim 1, wherein at least two inverters are arranged in sequence along the first direction.
